(19) United States
(12) Patent Application Publication
(10) Pub. No.: US 2023/0324789 A1
(43) Pub. Date: Oct. 12, 2023

(54) PHOTOSENSITIVE RESIN COMPOSITION, PERMANENT RESIST, METHOD FOR FORMING PERMANENT RESIST, AND METHOD FOR INSPECTING PERMANENT RESIST CURED FILM

(71) Applicant: RESONAC CORPORATION, Tokyo (JP)

(72) Inventors: Yu AOKI, Tokyo (JP); Yoshimi HAMANO, Tokyo (JP); Teruaki SUZUKI, Tokyo (JP)

(21) Appl. No.: 18/023,952

(22) PCT Filed: Jul. 5, 2021
(86) PCT No.: PCT/JP2021/025320

§ 371 Date: Feb. 28, 2023

(51) Int. Cl. G03F 7/004; G03F 7/033; G03F 7/038; G01N 21/64

(52) U.S. Cl. CPC G03F 7/0045; G03F 7/033; G03F 7/0388; G01N 21/64

(57) ABSTRACT

An aspect of the present disclosure relates to a method for forming a permanent resist, the method including a step of coating a photosensitive resin composition, which contains a base polymer and a compound having an absorption peak at 360 to 500 nm and emitting light by light irradiation, to a part or the entire surface of a substrate and drying the photosensitive resin composition to form a resin film, a step of exposing at least a part of the resin film, a step of developing the exposed resin film to form a patterned resin film, and a step of heating the patterned resin film.

### TECHNICAL FIELD

The present disclosure relates to a photosensitive resin composition, a permanent resist, a method for forming a permanent resist, and a method for inspecting a cured film for a permanent resist.

### BACKGROUND ART

Along with performance enhancement in various electronic apparatuses, high integration of semiconductors is in progress. According to this, there is a demand that various performances are imparted to permanent resists (solder resists) which are formed on printed circuit boards, semiconductor package substrates, and the like.

As a photosensitive resin composition used for forming a permanent resist, for example, a photosensitive resin composition containing a novolac resin, an epoxy resin, and a photo-acid generator, a photosensitive resin composition containing an alkali-soluble epoxy compound having a carboxyl group and a photo-cationic polymerization initiator, and the like have been known (see, for example, Patent Literatures 1 and 2).

### CITATION LIST

### Patent Literature

Patent Literature 1: JP H09-087366 A
Patent Literature 2: WO 2008/010521 A1

### SUMMARY OF INVENTION

### Technical Problem

By inspecting the appearance of a permanent resist, a failure can be found at an earlier stage in the production of printed circuit boards, semiconductor package substrates, or the like. It is required for the photosensitive resin composition to form a permanent resist whose appearance can be inspected with a simple method.

An object of the present disclosure is to provide a photosensitive resin composition capable of forming a permanent resist whose appearance can be inspected with a simple method, a permanent resist whose appearance can be inspected with a simple method, a method for forming a permanent resist, and a method for inspecting a cured film for a permanent resist.

### Solution to Problem

An aspect of the present disclosure relates to a method for forming a permanent resist, the method including a step of coating a photosensitive resin composition, which contains a base polymer and a compound having an absorption peak at 360 to 500 nm and emitting light by light irradiation, to a part or the entire surface of a substrate and drying the photosensitive resin composition to form a resin film, a step of exposing at least a part of the resin film, a step of developing the exposed resin film to form a patterned resin film, and a step of heating the patterned resin film.

Another aspect of the present disclosure relates to a photosensitive resin composition for a permanent resist, the photosensitive resin composition containing a base polymer and a compound having an absorption peak at 360 to 500 nm and emitting light by light irradiation.

Still another aspect of the present disclosure relates to a permanent resist containing a cured product of a photosensitive resin composition which contains a base polymer and a compound having an absorption peak at 360 to 500 nm and emitting light by light irradiation, in which a fluorescence intensity of the permanent resist at an excitation wavelength of 405 nm or 480 nm is 10 times or more with respect to a fluorescence intensity of a standard film with a thickness of 10 μm, which contains a cured product of a resin composition containing 100 parts by mass of a p-hydroxystyrene/styrene copolymer and 25 parts by mass of 4,4′,4″-ethylidenetris[2,6-(methoxymethyl)phenol], at an excitation wavelength of 405 nm or 480 nm.

Still another aspect of the present disclosure relates to a method for inspecting a cured film for a permanent resist, the method including a step of coating a resin composition, which contains 100 parts by mass of a p-hydroxystyrene/styrene copolymer and 25 parts by mass of 4,4′,4″-ethylidenetris[2,6-(methoxymethyl)phenol], onto a glass substrate, drying the resin composition, and then performing a heating treatment at 200° C. to form a standard film with a thickness of 10 μm which contains a cured product of the resin composition, a step of coating a photosensitive resin composition onto a glass substrate, drying the photosensitive resin composition, and then performing a heating treatment to form a cured film containing a cured product of the photosensitive resin composition, and a step of measuring a fluorescence intensity of each of the standard film and the cured film at excitation wavelengths of 405 nm and 480 nm, wherein a cured film in which a fluorescence intensity of the cured film at an excitation wavelength of 405 nm or 480 nm is 10 times or more with respect to a fluorescence intensity of the standard film at an excitation wavelength of 405 nm or 480 nm is selected.

### Advantageous Effects of Invention

According to the present disclosure, it is possible to provide a photosensitive resin composition capable of forming a permanent resist whose appearance can be inspected with a simple method, a permanent resist whose appearance can be inspected with a simple method, a method for forming a permanent resist, and a method for inspecting a cured film for a permanent resist.

### DESCRIPTION OF EMBODIMENTS

Hereinafter, the present disclosure will be described in detail. In the present specification, the term “step” includes not only an independent step but also a step that cannot be clearly distinguished from other steps as long as an intended action of the step is achieved. The term “layer” includes a structure having a shape which is formed on a part, in addition to a structure having a shape which is formed on the whole surface, when the layer has been observed as a plan view. A numerical range that has been indicated by use of “to” indicates the range that includes the numerical values which are described before and after “to,” as the minimum value and the maximum value, respectively. In the numerical ranges that are described stepwise in the present specification, the upper limit value or the lower limit value of a numerical range of a certain stage may be substituted by the upper limit value or the lower limit value of a numerical range of another stage. In a numerical range described in the present specification, the upper limit value or the lower limit value of the numerical range may be substituted by a value disclosed in the Examples.

In the present specification, the term “(meth)acrylic acid” means at least one of “acrylic acid” and “methacrylic acid” corresponding thereto, and the same applies to other analogous expressions such as (meth)acrylate. In the present specification, the term “solid content” refers to a non-volatile content contained in a photosensitive resin composition excluding volatile substances such as water or a solvent, refers to a component remaining without volatile in drying of the resin composition, and includes a component present in a liquid, syrupy, and waxy state at room temperature near 25° C.

[Photosensitive Resin Composition]

A photosensitive resin composition for a permanent resist according to an embodiment contains a base polymer and a compound having an absorption peak at 360 to 500 nm and emitting light by light irradiation. The photosensitive resin composition according to the present embodiment may be a positive-type photosensitive resin composition and may be a negative-type photosensitive resin composition.

(Compound Having Absorption Peak at 360 to 500 nm and Emitting Light by Light Irradiation)

By containing a compound having an absorption peak at 360 to 500 nm and emitting light by light irradiation as a component (X), the photosensitive resin composition can form a permanent resist whose appearance can be inspected with a simple method.

The maximum absorption wavelength (λmax) of the component (X) is in a range of 360 to 500 nm, and λmax may be 370 nm or more, 385 nm or more, or 400 nm or more from the viewpoint of increasing a fluorescence intensity at an excitation wavelength of 405 nm, and may be 495 nm or less, 490 nm or less, or 485 nm or less from the viewpoint of increasing a fluorescence intensity at an excitation wavelength of 480 nm.

The melting point of the component (X) is, for example, 80 to 250° C., may be 90° C. or higher, 100° C. or higher, or 150° C. from the viewpoint of enhancing the heat resistance of the permanent resist, and may be 245° C. or lower, 240° C. or lower, or 235° C. or lower from the viewpoint of improving compatibility with the base polymer.

Examples of the component (X) include a coumarin compound and a benzoxazole compound. The component (X) may be used singly or in combination of two or more kinds thereof.

As the coumarin compound, for example, a compound represented by Formula (1) below can be used.

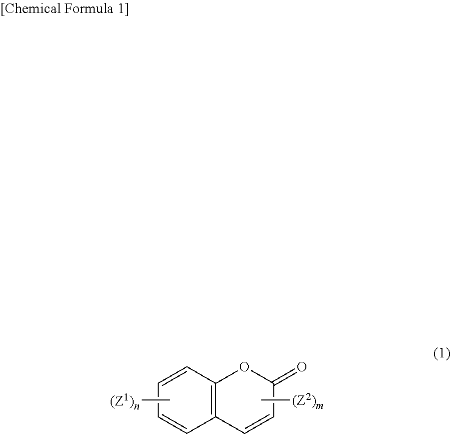

In Formula (1), Z¹ and Z² each independently represent a halogen atom, an alkyl group having 1 to 20 carbon atoms, a cycloalkyl group having 3 to 10 carbon atoms, an aryl group having 6 to 14 carbon atoms, an amino group, an alkylamino group having 1 to 10 carbon atoms, a dialkylamino group having 1 to 20 carbon atoms, a mercapto group, an alkylmercapto group having 1 to 10 carbon atoms, an allyl group, an hydroxyalkyl group having 1 to 20 carbon atoms, a carboxyl group, a carboxyalkyl group in which the number of carbon atoms of the alkyl group is 1 to 10, an acyl group in which the number of carbon atoms of the alkyl group is 1 to 10, an alkoxyl group having 1 to 20 carbon atoms, an alkoxycarbonyl group having 1 to 20 carbon atoms, or a group including a heterocyclic ring, n represents an integer of 0 to 4, and m represents an integer of 0 to 2. Note that, at least two of n Z¹'s and m Z²'s may form a ring.

Examples of the halogen atom in Formula (1) include fluorine, chlorine, bromine, iodine, and astatine. Examples of the alkyl group having 1 to 20 carbon atoms include a methyl group, an ethyl group, an n-propyl group, an isopropyl group, an n-butyl group, an isobutyl group, a sec-butyl group, a tert-butyl group, a pentyl group, an isopentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an icosyl group, and structural isomers thereof. Examples of the cycloalkyl group having 3 to 10 carbon atoms include a cyclopropyl group, a cyclobutyl group, a cyclopentyl group, a cyclohexyl group, a cycloheptyl group, and a cyclooctyl group. Examples of the aryl group having 6 to 14 carbon atoms include a phenyl group, a tolyl group, a xylyl group, a biphenyl group, a naphthyl group, an anthryl group, and a phenanthryl group, and these groups may be substituted with a halogen atom, an amino group, a nitro group, a cyano group, a mercapto group, an allyl group, an alkyl group having 1 to 20 carbon atoms, or the like. Examples of the alkylamino group having 1 to 10 carbon atoms include a methylamino group, an ethylamino group, a propylamino group, and an isopropylamino group. Examples of the dialkylamino group having 2 to 20 carbon atoms include a dimethylamino group, a diethylamino group, a dipropylamino group, and a diisopropylamino group. Examples of the alkylmercapto group having 1 to 10 carbon atoms include a methylmercapto group, an ethylmercapto group, and a propylmercapto group. Examples of the hydroxyalkyl group having 1 to 20 carbon atoms include a hydroxymethyl group, a hydroxyethyl group, a hydroxypropyl group, a hydroxyisopropyl group, and a hydroxybutyl group. Examples of the carboxyalkyl group in which the number of carbon atoms of the alkyl group is 1 to 10 include a carboxymethyl group, a carboxyethyl group, a carboxypropyl group, and a carboxybutyl group. Examples of the acyl group in which the number of carbon atoms of the alkyl group is 1 to 10 include a formyl group, an acetyl group, a propionyl group, a butyryl group, an isobutyryl group, a valeryl group, an isovaleryl group, and a pivaloyl group. Examples of the alkoxy group having 1 to 20 carbon atoms include a methoxy group, an ethoxy group, a propoxy group, and a butoxy group. Examples of the alkoxycarbonyl group having 1 to 20 carbon atoms include a methoxycarbonyl group, an ethoxycarbonyl group, a propoxycarbonyl group, and a butoxycarbonyl group. Examples of the group including a heterocyclic ring include a benzothiazolyl group, a furyl group, a thienyl group, a pyrrolyl group, a thiazolyl group, an indolyl group, and a quinolyl group.

In Formula (1), it is preferable that Z¹ and Z² each independently represent an alkyl group having 1 to 20 carbon atoms, an amino group, an alkylamino group having 1 to 10 carbon atoms, or a dialkylamino group having 1 to 20 carbon atoms. Also in this case, at least two of n Z¹'s and m Z²'s may form a ring.

From the viewpoint of resolution and photosensitivity, the coumarin compound represented by Formula (1) may be a compound represented by Formula (2) below. In Formula (2), Z¹, Z², and m have the same definition as in Z¹, Z², and m described above, Z¹¹ and Z¹² each independently represent a hydrogen atom or an alkyl group having 1 to 20 carbon atoms, and r represents an integer of 0 to 3. At least two of r Z¹'s, m Z²'s, m Z¹¹'s, and m Z¹²'s may form a ring. In the compound represented by Formula (2) below, it is preferable that Z¹¹ and Z¹² each independently represent an alkyl group having 1 to 10 carbon atoms, it is more preferable that Z¹¹ and Z¹² each independently represent an alkyl group having 1 to 6 carbon atoms. Preferred Z¹ and Z² are the same as described above.

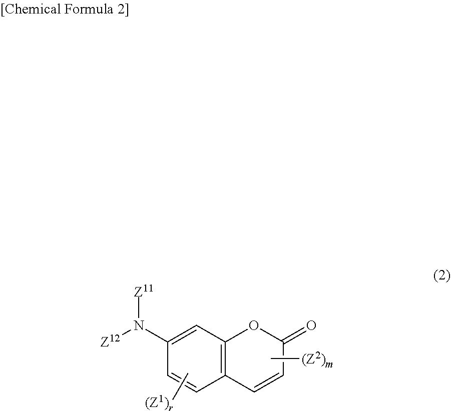

Examples of an embodiment that is the compound represented by Formula (2) in which at least two of m Z²'s, m Z¹¹'s, and m Z¹²'s form a ring include a compound represented by Formula (3) below and a compound represented by Formula (4) below.

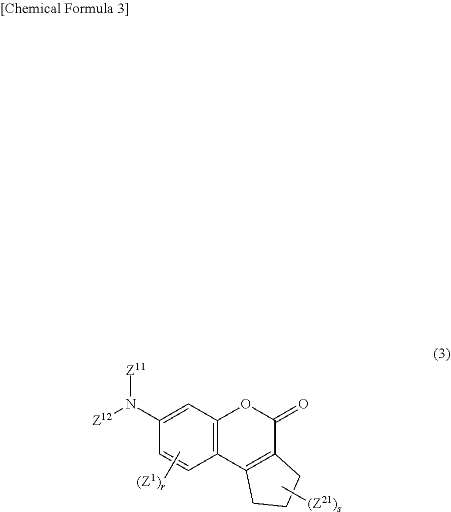

In Formula (3), Z¹, Z¹¹, Z¹², and r have the same definition as in Z¹, Z¹¹, Z¹², and r described above, and Z²¹ represents the same atom or group as in Z¹ described above. s represents an integer of 0 to 8. Preferred Z¹, Z¹¹, and Z¹² are the same as described above.

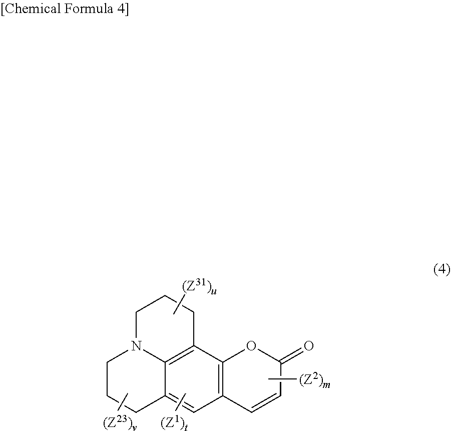

In Formula (4), Z¹, Z², and m have the same definition as in Z¹, Z², and m described above, and Z³1 and Z³² each independently represent the same atom or group as in Z¹ described above. t represents an integer of 0 or 1, u represents an integer of 0 to 6, and v represents an integer of 0 to 6. Preferred Z¹ and Z² are the same as described above.

Examples of the compound represented by Formula (2) (including the compounds represented by Formulas (3) and (4)) include 7-amino-4-methylcoumarin, 7-dimethylamino-4-methylcoumarin, 7-diethylamino-4-methylcoumarin (a compound represented by Formula (5) below), 7-methylamino-4-methylcoumarin, 7-ethylamino-4-methylcoumarin, 4,6-dimethyl-7-ethylaminocoumarin (a compound represented by Formula (6) below), 4,6-diethyl-7-ethylaminocoumarin, 4,6-dimethyl-7-diethylaminocoumarin, 4,6-dimethyl-7-dimethylaminocoumarin, 4,6-diethyl-7-diethylaminocoumarin, 4,6-diethyl-7-dimethylaminocoumarin, 4,6-dimethyl-7-ethylaminocoumarin, 7-dimethylaminocyclopenta[c]coumarin (a compound represented by Formula (7) below), 7-aminocyclopenta[c]coumarin, 7-diethylaminocyclopenta[c]coumarin, 2,3,6,7,10,11-hexanehydro-1H,5H-cyclopenta[3,4][1]benzopyrano[6,7,8-ij]quinolizine 12(9H)-one, 7-diethylamino-5′,7′-dimethoxy-3,3′-carbonylbiscoumarin, 3,3′-carbonylbis[7-(diethylamino)coumarin], 7-(diethylamino)-3-(2-thienyl)coumarin, and a compound represented by Formula (8) below.

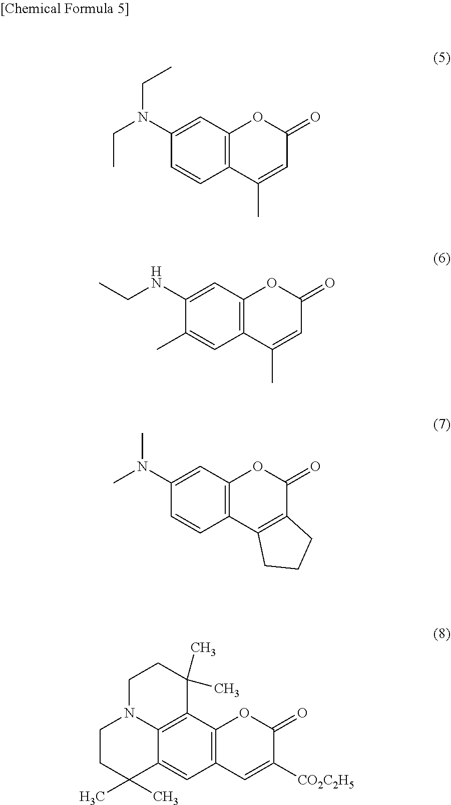 [SMILES: CCN(CC)c1ccc2c(C)cc(=O)oc2c1 ; CCNc1cc2oc(=O)cc(C)c2cc1C ; CN(C)c1ccc2c3c(c(=O)oc2c1)CCC3 ; CCOC(=O)c1cc2cc3c4c(c2oc1=O)C(C)(C)CCN4CCC3(C)C]

Examples of a coumarin compound other than the above-described coumarin compounds include 3-benzoyl-7-diethylaminocoumarin, 7-diethylamino-4-methylcoumarin, 7-diethylamino-3-phenylcoumarin, 3,3′-carbonylbis(7-diethylaminocoumarin), and 2,3,6,7-tetrahydro-9-methyl-1H,5H,11H-[1]benzopyrano[6,7,8-ij]quinolizin-11-one.

Examples of the benzoxazole compound include 2,5-bis(5-tert-butyl-2-benzoxazolyl)thiophene.

The content of the component (X) may be 0.1 parts by mass or more, 0.15 parts by mass or more, or 0.2 parts by mass or more from the viewpoint of increasing a fluorescence intensity and may be 3.0 parts by mass or less, 2.0 parts by mass or less, or 1.5 parts by mass or less from the viewpoint of compatibility with other components, with respect of 100 parts by mass of the base polymer.

(Base Polymer)

The photosensitive resin composition according to the present embodiment contains a base polymer as a component (A). The component (A) preferably contains a resin having a phenolic hydroxyl group or a resin having an ethylenically unsaturated group with photopolymerizability.

As the resin having a phenolic hydroxyl group, for example, at least one selected from the group consisting of a hydroxystyrene-based resin, a phenolic resin, and a polybenzoxazole precursor is exemplified. The resin having a phenolic hydroxyl group may be an alkali-soluble resin.

The hydroxystyrene-based resin is an alkali-soluble resin having a structural unit represented by Formula (21) below.

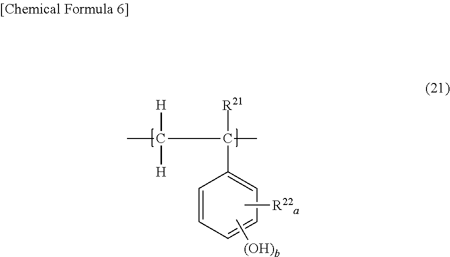

In Formula (21), R²¹ represents a hydrogen atom or a methyl group, R²² represents an alkyl group having 1 to 10 carbon atoms, an aryl group having 6 to 10 carbon atoms, or an alkoxy group having 1 to 10 carbon atoms, a represents an integer of 0 to 3, and b represents an integer of 1 to 3. The sum of a and b is 5 or less.

Examples of the alkyl group having 1 to 10 carbon atoms represented by R²² include a methyl group, an ethyl group, a propyl group, a butyl group, a pentyl group, a hexyl group, a heptyl group, an octyl group, a nonyl group, and a decyl group. These groups may be linear and may be branched. Examples of the aryl group having 6 to 10 carbon atoms represented by R²² include a phenyl group and a naphthyl group. Examples of the alkoxy group having 1 to 10 carbon atoms represented by R²² include a methoxy group, an ethoxy group, a propoxy group, a butoxy group, a pentoxy group, a hexoxy group, a heptoxy group, an octoxy group, a nonoxy group, and a decoxy group. These groups may be linear and may be branched.

The hydroxystyrene-based resin can be obtained by polymerizing monomers providing the structural unit represented by Formula (21). Examples of the monomers providing the structural unit represented by Formula (21) include p-hydroxystyrene, m-hydroxystyrene, o-hydroxystyrene, p-isopropenylphenol, m-isopropenylphenol, and o-isopropenylphenol. These monomers can be used singly or in combination of two or more kinds thereof.

A method for producing a hydroxystyrene-based resin is not limited. The hydroxystyrene-based resin can be produced, for example, by protecting the hydroxyl group of the monomers providing the structural unit represented by Formula (21) with a tert-butyl group, an acetyl group, or the like to obtain the monomers with the protected hydroxyl group, polymerizing the monomers with the protected hydroxyl group to obtain a polymer, and then deprotecting the polymer by a known method (deprotecting the polymer in the presence of an acid catalyst to convert the structural unit into a hydroxystyrene-based structural unit).

The hydroxystyrene-based resin may be a homopolymer of the monomer providing the structural unit represented by Formula (21) and may be a copolymer of the monomer providing the structural unit represented by Formula (21) and a monomer other than the monomer providing the structural unit. In a case where the hydroxystyrene-based resin is a copolymer, the ratio of the structural unit represented by Formula (21) in the copolymer may be 10 to 100 mol %, 20 to 95 mol %, 30 to 90 mol %, or 50 to 85 mol %, on the basis of the total molar quantity of the whole components constituting the component (A), from the viewpoint of the dissolubility at the exposed area with respect to an alkaline developing solution.

The hydroxystyrene-based resin may further have a structural unit represented by Formula (22) below from the viewpoint of improving the dissolution-inhibiting property at the unexposed area with respect to an alkaline developing solution.

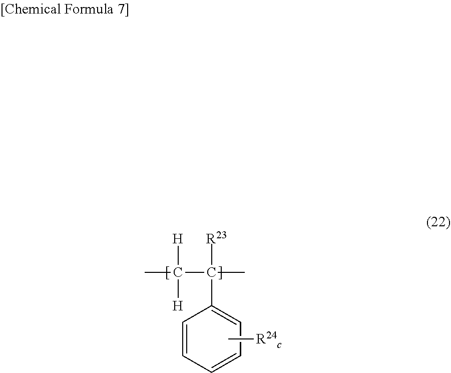

In Formula (22), R²³ represents a hydrogen atom or a methyl group, R²⁴ represents an alkyl group having 1 to 10 carbon atoms, an aryl group having 6 to 10 carbon atoms, or an alkoxy group having 1 to 10 carbon atoms, and c represents an integer of 0 to 3.

As the alkyl group having 1 to 10 carbon atoms, the aryl group having 6 to 10 carbon atoms, or the alkoxy group having 1 to 10 carbon atoms represented by R²⁴, the same groups as in R²² can be exemplified, respectively.

An alkali-soluble resin having the structural unit represented by Formula (22) is obtained by using a monomer providing the structural unit represented by Formula (22). Examples of the monomer providing the structural unit represented by Formula (22) include aromatic vinyl compounds such as styrene, α-methylstyrene, o-methylstyrene, m-methylstyrene, p-methylstyrene, o-methoxystyrene, m-methoxystyrene, and p-methoxystyrene. These monomers can be used singly or in combination of two or more kinds thereof.

In a case where the hydroxystyrene-based resin is the alkali-soluble resin having the structural unit represented by Formula (22), the ratio of the structural unit represented by Formula (22) may be 1 to 90 mol %, 3 to 80 mol %, 5 to 70 mol %, or 10 to 50 mol %, on the basis of the total molar quantity of the whole components constituting the component (A), from the viewpoint of the dissolution-inhibiting property at the unexposed area with respect to an alkaline developing solution and the water-absorbing property of the cured film.

The hydroxystyrene-based resin may have a structural unit based on a (meth)acrylic acid ester from the viewpoint of reducing elastic modulus. The (meth)acrylic acid ester may be a compound having an alkyl group or a hydroxyalkyl group.

Examples of the (meth)acrylic acid ester include alkyl (meth)acrylate esters such as methyl (meth)acrylate, ethyl (meth)acrylate, propyl (meth)acrylate, butyl (meth)acrylate, pentyl(meth)acrylate, hexyl (meth)acrylate, heptyl (meth)acrylate, octyl (meth)acrylate, nonyl (meth)acrylate, and decyl (meth)acrylate; and hydroxyalkyl (meth)acrylate esters such as hydroxymethyl (meth)acrylate, hydroxyethyl (meth)acrylate, hydroxypropyl (meth)acrylate, hydroxybutyl (meth)acrylate, hydroxypentyl (meth)acrylate, hydroxyhexyl (meth)acrylate, hydroxyheptyl (meth)acrylate, hydroxyoctyl (meth)acrylate, hydroxynonyl (meth)acrylate, and hydroxydecyl (meth)acrylate. These monomers can be used singly or in combination of two or more kinds thereof.

In a case where the hydroxystyrene-based resin is an alkali-soluble resin having a structural unit based on a (meth)acrylic acid ester, the ratio of the structural unit based on a (meth)acrylic acid ester may be 1 to 90 mol %, 3 to 80 mol %, 5 to 70 mol %, or 5 to 50 mol %, on the basis of the total molar quantity of the whole components constituting the component (A), from the viewpoint of the mechanical properties of a patterned cured film.

The phenolic resin may be a polycondensation product of phenol or a derivative thereof with an aldehyde. The polycondensation is usually performed in the presence of a catalyst of an acid, a base, or the like. A phenolic resin obtained in the case of using an acid catalyst is called particularly a novolac type phenolic resin. Examples of the novolac type phenolic resin include a phenol/formaldehyde novolac resin, a cresol/formaldehyde novolac resin, a xylenol/formaldehyde novolac resin, a resorcinol/formaldehyde novolac resin, and a phenol-naphthol/formaldehyde novolac resin.

Examples of phenol derivatives constituting the phenolic resin include alkylphenols such as o-cresol, m-cresol, p-cresol, o-ethylphenol, m-ethylphenol, p-ethylphenol, o-butylphenol, m-butylphenol, p-butylphenol, 2,3-xylenol, 2,4-xylenol, 2,5-xylenol, 2,6-xylenol, 3,4-xylenol, 3,5-xylenol, 2,3,5-trimethylphenol, and 3,4,5-trimethylphenol; alkoxyphenols such as methoxyphenol and 2-methoxy-4-methylphenol; alkenylphenols such as vinylphenol and allylphenol; aralkylphenols such as benzylphenol; alkoxycarbonylphenols such as methoxycarbonylphenol; arylcarbonylphenols such as benzoyloxyphenol; halogenated phenols such as chlorophenol; polyhydroxybenzenes such as catechol, resorcinol, and pyrogallol; bisphenols such as bisphenol A and bisphenol F; naphthol derivatives such as α-naphthol and β-naphthol; hydroxyalkylphenols such as p-hydroxyphenyl-2-ethanol, p-hydroxyphenyl-3-propanol, and p-hydroxyphenyl-4-butanol; hydroxyalkylcresols such as hydroxyethylcresol; alcoholic hydroxyl group-containing phenol derivatives such as monoethylene oxide adducts of bisphenol and monopropylene oxide adducts of bisphenol; and carboxyl group-containing phenol derivatives such as p-hydroxyphenylacetic acid, p-hydroxyphenylpropionic acid, p-hydroxyphenylbutanoic acid, p-hydroxycinnamic acid, hydroxybenzoic acid, hydroxyphenylbenzoic acid, hydroxyphenoxybenzoic acid, and diphenolic acid. These can be used singly or in combination of two or more kinds thereof.

Examples of aldehydes constituting the phenolic resin include formaldehyde, acetaldehyde, furfural, benzaldehyde, hydroxybenzaldehyde, methoxybenzaldehyde, hydroxyphenylacetaldehyde, methoxyphenylacetaldehyde, crotonaldehyde, chloroacetaldehyde, chlorophenylacetaldehyde, glyceraldehyde, glyoxylic acid, methyl glyoxylate, phenyl glyoxylate, hydroxyphenyl glyoxylate, formylacetic acid, methyl formylacetate, 2-formylpropionic acid, and methyl 2-formylpropionate. These may be used singly or in combination of two or more kinds thereof. Furthermore, formaldehyde precursors such as paraformaldehyde and trioxane; and ketone compounds such as acetone, pyruvic acid, levulinic acid, 4-acetylbutyric acid, acetonedicarboxylic acid, and 3,3′-4,4′-benzophenonetetracarboxylic acid may be used in the reaction.

Examples of phenols include phenol, o-cresol, m-cresol, p-cresol, o-ethylphenol, m-ethylphenol, p-ethylphenol, o-butylphenol, m-butylphenol, p-butylphenol, 2,3-xylenol, 2,4-xylenol, 2,5-xylenol, 2,6-xylenol, 3,4-xylenol, 3,5-xylenol, 2,3,5-trimethylphenol, 3,4,5-trimethylphenol, catechol, resorcinol, pyrogallol, α-naphthol, and p3-naphthol. The phenols can be used singly or in combination of two or more kinds thereof.

The phenolic resin may be a resin having a bisphenol imide skeleton. The bisphenol imide skeleton may be a structure based on the reaction between tetracarboxylic dianhydride and an aminophenol compound.

Examples of the polybenzoxazole precursor include polyhydroxy amide. As the polyhydroxy amide, a conventionally known one can be used.

Examples of the resin having an ethylenically unsaturated group with photopolymerizability include polyimide precursors such as polyamic acid ester in which the whole or a part of the carboxyl group in polyamic acid is esterified. The polyamic acid ester preferably has an ethylenically unsaturated group with photopolymerizability. The polyamic acid ester may be a reactant of diamine, tetracarboxylic dianhydride, and a compound having an ethylenically unsaturated group with photopolymerizability.

Examples of the diamine include 4,4′-diaminodiphenyl ether, 2,2-bis(4-aminophenyl)hexafluoropropane, polyoxypropylenediamine, and 2,2′-dimethylbiphenyl-4,4′-diamine. Examples of the tetracarboxylic dianhydride include biphenyl tetracarboxylic dianhydride and 4,4′-diphenyl ether tetracarboxylic dianhydride. Examples of the compound having an ethylenically unsaturated group with photopolymerizability include 2-hydroxyethyl (meth)acrylate (HEMA).

The weight average molecular weight (Mw) of the component (A) may be 3500 to 100000, 4000 to 80000, 5000 to 50000, or 6000 to 30000.

In the present specification, Mw is a value obtained by measurement by gel permeation chromatography (GPC) and conversion with a standard polystyrene calibration curve. As a measurement device, for example, high-performance liquid chromatography (manufactured by SHIMADZU CORPORATION, trade name “C-R4A”) can be used.

(Thermal Crosslinking Agent)

The photosensitive resin composition may contain a thermal crosslinking agent as a component (B1) in the case of containing the resin having a phenolic hydroxyl group as the component (A). The component (B1) is a compound having a structure that can form a crosslinking structure by the reaction with the component (A) when a patterned resin film is heated and cured. This can prevent brittleness of the film and melting of the film. Examples of the component (B1) include a compound having a phenolic hydroxyl group, a compound having an alkoxymethyl group, and a compound having an epoxy group. The component (B1) may be used singly or in combination of two or more kinds thereof.

The “compound having a phenolic hydroxyl group” described herein does not include the resin having a phenolic hydroxyl group of the component (A). The compound having a phenolic hydroxyl group as the thermal crosslinking agent not only serves as a thermal crosslinking agent but can also both increase the dissolution rate at the exposed area during development with an aqueous alkali solution and improve the sensitivity. The Mw of such a compound having a phenolic hydroxyl group may be 3000 or less, 2000 or less, or 1500 or less in consideration of dissolubility with respect to an aqueous alkali solution and balance between photosensitive properties and a mechanical strength.

As the compound having an alkoxymethyl group, a conventionally known one can be used. The compound having an alkoxymethyl group may have a methoxymethyl group and may have four or more methoxymethyl groups from the viewpoint that high reactivity and heat resistance can be provided. The compound having an alkoxymethyl group may be a compound further having a phenolic hydroxyl group. The compound having an alkoxymethyl group may be a compound selected from compounds represented by the following formulae since an excellent balance between a dissolution-accelerating effect at the exposed area and the mechanical strength of the cured film is attained.

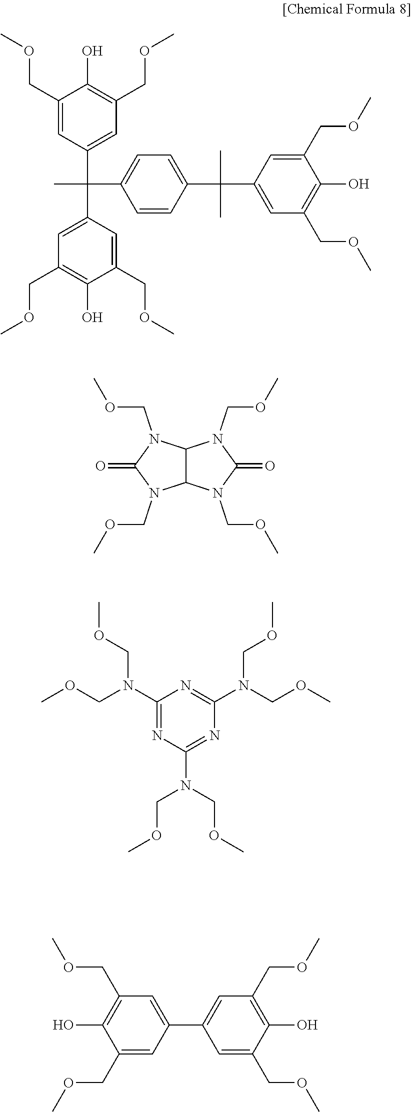

As the compound having an epoxy group, a conventionally known one can be used. Examples of the compound having an epoxy group include a bisphenol A-type epoxy compound, a bisphenol F-type epoxy compound, a phenol-novolac-type epoxy compound, a cresol-novolac-type epoxy compound, an alicyclic epoxy compound, a glycidylamine-type epoxy compound, a heterocyclic epoxy compound, a halogenated epoxy compound, and polyalkyleneglycol diglycidyl ether.

As the component (B1), other than the above-described compounds, for example, aromatic compounds having a hydroxymethyl group, such as bis[3,4-bis(hydroxymethyl)phenyl]ether and 1,3,5-tris(1-hydroxy-1-methylethyl)benzene, compounds having a maleimide group, such as bis(4-maleimidephenyl)methane and 2,2-bis[4-(4′-maleimidephenoxy)phenyl]propane, compounds having a norbornane skeleton, polyfunctional acrylate compounds, compounds having an oxetanyl group, compounds having a vinyl group, or blocked isocyanato compounds can also be used.

The content of the component (B1) in the photosensitive resin composition may be 1 to 70 parts by mass, 2 to 50 parts by mass, or 3 to 40 parts by mass, with respect to 100 parts by mass of the component (A), from the viewpoint of the developability of the resin film and physical properties of the cured film.

(Photopolymerizable Compound)

The photosensitive resin composition may contain a photopolymerizable compound as a component (B2) in the case of containing the resin having an ethylenically unsaturated group as the component (A). The component (B2) may be used singly or in combination of two or more kinds thereof.

As the photopolymerizable compound, a compound having an ethylenically unsaturated group with photopolymerizability can be used. Examples of the photopolymerizable compound include α,β-unsaturated carboxylic acid esters of polyhydric alcohols, bisphenol-type (meth)acrylates, α,β-unsaturated carboxylic acid adducts of glycidyl group-containing compounds, (meth)acrylates having a urethane bond, nonylphenoxypolyethylene oxyacrylate, (meth)acrylates having a phthalic acid skeleton, and alkyl (meth)acrylate esters.

Examples of the α,β-unsaturated carboxylic acid esters of polyhydric alcohols include polyethylene glycol di(meth)acrylate in which the number of ethylene groups is 2 to 14, polypropylene glycol di(meth)acrylate in which the number of propylene groups is 2 to 14, polyethylene-polypropylene glycol di(meth)acrylate in which the number of ethylene groups is 2 to 14 and the number of propylene groups is 2 to 14, trimethylol propane di(meth)acrylate, trimethylolpropane tri(meth)acrylate, EO-modified trimethylolpropane tri(meth)acrylate, PO-modified trimethylolpropane tri(meth)acrylate, EO, PO-modified trimethylolpropane tri(meth)acrylate, tetramethylolmethane tri(meth)acrylate, tetramethylolmethane tetra(meth)acrylate, and a (meth)acrylate compound having a skeleton derived from dipentaerythritol or pentaerythritol. The term “EO-modified” means having a block structure of an ethylene oxide (EO) group, and the term “PO-modified” means having a block structure of a propylene oxide (PO) group.

The content of the component (B2) in the photosensitive resin composition may be 1 to 50 parts by mass, 2 to 40 parts by mass, or 3 to 30 parts by mass, with respect to 100 parts by mass of the component (A), from the viewpoint of the developability of the resin film and physical properties of the cured film.

(Photosensitizing Agent)

The photosensitive resin composition according to the present embodiment can contain a photosensitizing agent as a component (C). In a case where the photosensitive resin composition contains the resin having a phenolic hydroxyl group as the component (A), a photo-acid generator generating an acid by light irradiation can be used as a component (C1). In a case where the photosensitive resin composition contains the resin having an ethylenically unsaturated group as the component (A), a photopolymerization initiator generating radicals by light irradiation can be used as a component (C2).

The photo-acid generator has the function of generating an acid by light irradiation and increasing the solubility of the light-irradiated area in an aqueous alkali solution. Examples of the photo-acid generator include an o-quinonediazide compound, an aryldiazonium salt, a diaryliodonium salt, and a triarylsulfonium salt. The photo-acid generator may be used singly or in combination of two or more kinds thereof according to purposes, use applications, and the like.

The o-quinonediazide compound is preferably used as the photo-acid generator from the viewpoint of high sensitivity. As the o-quinonediazide compound, for example, a compound obtained by the condensation reaction between o-quinonediazidesulfonyl chloride and a hydroxy compound, an amino compound, or the like in the presence of a base excision agent can be used. The reaction temperature may be 0 to 40° C., and the reaction time may be 1 to 10 hours.

Examples of the o-quinonediazidesulfonyl chloride include benzoquinone-1,2-diazide-4-sulfonyl chloride, naphthoquinone-1,2-diazide-5-sulfonyl chloride, and naphthoquinone-1,2-diazide-6-sulfonyl chloride.

Examples of the hydroxy compound include hydroquinone, resorcinol, pyrogallol, bisphenol A, bis(4-hydroxyphenyl)methane, 1,1-bis(4-hydroxyphenyl)-1-[4-{1-(4-hydroxyphenyl)-1-methylethyl}phenyl]ethane, 2,2-bis(4-hydroxyphenyl)hexafluoropropane, 2,3,4-trihydroxybenzophenone, 2,3,4,4′-tetrahydroxybenzophenone, 2,2′,4,4′-tetrahydroxybenzophenone, 2,3,4,2′,3′-pentahydroxybenzophenone, 2,3,4,3′,4′,5′-hexahydroxybenzophenone, bis(2,3,4-trihydroxyphenyl)methane, bis(2,3,4-trihydroxyphenyl)propane, 4b,5,9b,10-tetrahydro-1,3,6,8-tetrahydroxy-5,10-dimethylindeno[2,1-a]indene, tris(4-hydroxyphenyl)methane, and tris(4-hydroxyphenyl)ethane.

Examples of the amino compound include p-phenylenediamine, m-phenylenediamine, 4,4′-diaminodiphenyl ether, 4,4′-diaminodiphenyl methane, 4,4′-diaminodiphenyl sulfone, 4,4′-diaminodiphenyl sulfide, o-aminophenol, m-aminophenol, p-aminophenol, 3,3′-diamino-4,4′-dihydroxybiphenyl, 4,4′-diamino-3,3′-dihydroxybiphenyl, bis(3-amino-4-hydroxyphenyl)propane, bis(4-amino-3-hydroxyphenyl)propane, bis(3-amino-4-hydroxyphenyl)sulfone, bis(4-amino-3-hydroxyphenyl)sulfone, bis(3-amino-4-hydroxyphenyl)hexafluoropropane, and bis(4-amino-3-hydroxyphenyl)hexafluoropropane.

From the viewpoint of reactivity when the o-quinonediazide compound is synthesized and the viewpoint that an absorption wavelength range is appropriate when the resin film is exposed, it is preferable to use a compound obtained by the condensation reaction between 1,1-bis(4-hydroxyphenyl)-1-[4-{1-(4-hydroxyphenyl)-1-methylethyl}phenyl]ethane and 1-naphthoquinone-2-diazide-5-sulfonyl chloride, or a compound obtained by the condensation reaction between tris(4-hydroxyphenyl)methane or tris(4-hydroxyphenyl)ethane and 1-naphthoquinone-2-diazide-5-sulfonyl chloride.

Examples of the dehydrochlorinating agent include sodium carbonate, sodium hydroxide, sodium hydrogencarbonate, potassium carbonate, potassium hydroxide, trimethylamine, triethylamine, and pyridine. Examples of the reaction solvent include dioxane, acetone, methyl ethyl ketone, tetrahydrofuran, diethyl ether, and N-methyl-2-pyrrolidone.

The o-quinonediazidesulfonyl chloride and the hydroxy compound and/or the amino compound are preferably blended so that the total number of moles of hydroxy groups and amino groups is 0.5 to 1 mol with respect to 1 mol of the o-quinonediazidesulfonyl chloride. A preferred blending ratio of the dehydrochlorinating agent and the o-quinonediazidesulfonyl chloride is in a range of 0.95/1 mol to 1/0.95 mol equivalents.

Examples of the photopolymerization initiator include an alkylphenone-based photopolymerization initiator, an acylphosphine-based photopolymerization initiator, an intramolecular hydrogen withdrawing type photopolymerization initiator, and a cation-based photopolymerization initiator. Examples of commercially available products of these photopolymerization initiators include Omnirad 651, Omnirad 184, Omnirad 1173, Omnirad 2959, Omnirad 127, Omnirad 907, Omnirad 369, Omnirad 379EG, Omnirad 819, Omnirad MBF, Omnirad TPO, and Omnirad 784 manufactured by IGM Resins; and Irgacure OXE01, Irgacure OXE02, Irgacure OXE03, and Irgacure OXE04 manufactured by BASF. The photopolymerization initiator may be used singly or in combination of two or more kinds thereof according to purposes, use applications, and the like.

The content of the component (C) may be 1 to 30 parts by mass, 2 to 25 parts by mass, or 3 to 20 parts by mass, with respect to 100 parts by mass of the component (A), from the viewpoint of increasing a difference in dissolution rate between the exposed area and the unexposed area and obtaining more satisfactory sensitivity.

(Compound Generating Acid by Heating)

The photosensitive resin composition according to the embodiment may contain a compound generating an acid by heating.

By using the compound generating an acid by heating, an acid can be generated when the patterned resin film is heated, and a reaction of the component (A), a compound having a glycidyl group, and a low-molecular-weight compound having a phenolic hydroxyl group, that is, a thermal crosslinking reaction, is accelerated, so that the heat resistance of the patterned cured film is improved. Furthermore, since the compound generating an acid by heating generates an acid also by light irradiation, the dissolubility at the exposed area in an aqueous alkali solution is increased. Therefore, a difference in dissolubility with respect to the aqueous alkali solution between the unexposed area and the exposed area is further increased, so that resolution is further improved.

The compound generating an acid by heating is preferably, for example, a compound generating an acid by heating to 50 to 250° C. Examples of the compound generating an acid by heating include a salt formed from a strong acid and a base, such as an onium salt, and imidosulfonate.

The blending amount of the compound generating an acid by heating may be 0.1 to 30 parts by mass, 0.2 to 20 parts by mass, or 0.5 to 10 parts by mass, with respect to 100 parts by mass of the component (A).

(Elastomer)

The photosensitive resin composition according to the embodiment may contain an elastomer component. The elastomer is used for providing flexibility to a cured product of the photosensitive resin composition. As the elastomer, a conventionally known one can be used, but Tg of the polymer constituting the elastomer is preferably 20° C. or lower.

Examples of the elastomer include a styrene-based elastomer, an olefin-based elastomer, a urethane-based elastomer, a polyester-based elastomer, a polyamide-based elastomer, an acrylic-based elastomer, and a silicone-based elastomer. These can be used singly or in combination of two or more kinds thereof.

The blending amount of the elastomer may be 1 to 50 parts by mass or 5 to 30 parts by mass with respect to 100 parts by mass of the component (A). When the blending amount of the elastomer is 1 part by mass or more, there is a tendency that the thermal shock resistance of the cured film is improved, and when the blending amount of the elastomer is 50 parts by mass or less, there are tendencies that resolution and the heat resistance of the cured film to be obtained are difficult to be degraded and compatibility and dispersibility with other components are difficult to be degraded.

(Dissolution Accelerator)

The photosensitive resin composition according to the embodiment may contain a dissolution accelerator. When the dissolution accelerator is blended in the photosensitive resin composition, the dissolution rate at the exposed area during development with an aqueous alkali solution can be increased, and sensitivity and resolution can be improved. As the dissolution accelerator, a conventionally known one can be used. Examples of the dissolution accelerator include compounds having a carboxy group, a sulfo group, or a sulfonamide group. The blending amount in the case of using the dissolution accelerator can be determined depending on the dissolution rate with respect to an aqueous alkali solution, and, for example, can be set to 0.01 to 30 parts by mass with respect to 100 parts by mass of the component (A).

(Dissolution Inhibitor)

The photosensitive resin composition according to the embodiment may contain a dissolution inhibitor. The dissolution inhibitor is a compound inhibiting dissolubility of the component (A) with respect to an aqueous alkali solution, and is used for controlling the remaining film thickness, the developing time, and the contrast. Examples of the dissolution inhibitor include diphenyliodonium nitrate, bis(p-tert-butylphenyl)iodonium nitrate, diphenyliodonium bromide, diphenyliodonium chloride, and diphenyliodonium iodide. The blending amount in the case of using the dissolution inhibitor may be 0.01 to 20 parts by mass, 0.01 to 15 parts by mass, or 0.05 to 10 parts by mass, with respect to 100 parts by mass of the component (A), from the viewpoint of the permissible ranges for sensitivity and developing time.

(Coupling Agent)

The photosensitive resin composition according to the embodiment may contain a coupling agent. By blending the coupling agent in the photosensitive resin composition, adhesion of a patterned cured film to be formed to a substrate can be enhanced. Examples of the coupling agent include an organic silane compound and an alumichelate compound.

Examples of the organic silane compound include vinyltriethoxysilane, γ-glycidoxypropyltriethoxysilane, γ-methacryloxypropyltrimethoxysilane, ureapropyltriethoxysilane, methylphenylsilanediol, ethylphenylsilanediol, n-propylphenylsilanediol, isopropylphenylsilanediol, n-butylphenylsilanediol, isobutylphenylsilanediol, tert-butylphenylsilanediol, diphenylsilanediol, ethylmethylphenylsilanol, n-propylmethylphenylsilanol, isopropylmethylphenylsilanol, n-butylmethylphenylsilanol, isobutylmethylphenylsilanol, tert-butylmethylphenylsilanol, ethyl-n-propylphenylsilanol, ethylisopropylphenylsilanol, n-butylethylphenylsilanol, isobutylethylphenylsilanol, tert-butylethylphenylsilanol, methyldiphenylsilanol, ethyldiphenylsilanol, n-propyldiphenylsilanol, isopropyldiphenylsilanol, n-butyldiphenylsilanol, isobutyldiphenylsilanol, tert-butyldiphenylsilanol, phenylsilanetriol, 1,4-bis(trihydroxysilyl)benzene, 1,4-bis(methyldihydroxysilyl)benzene, 1,4-bis(ethyldihydroxysilyl)benzene, 1,4-bis(propyldihydroxysilyl)benzene, 1,4-bis(butyldihydroxysilyl)benzene, 1,4-bis(dimethylhydroxysilyl)benzene, 1,4-bis(diethylhydroxysilyl)benzene, 1,4-bis(dipropylhydroxysilyl)benzene, and 1,4-bis(dibutylhydroxysilyl)benzene.

The blending amount in the case of using the coupling agent is preferably 0.1 to 20 parts by mass and more preferably 0.5 to 10 parts by mass with respect to 100 parts by mass of the component (A).

(Surfactant or Leveling Agent)

The photosensitive resin composition according to the embodiment may contain a surfactant or a leveling agent. By blending the surfactant or the leveling agent in the photosensitive resin composition, coatability can be further improved. Specifically, for example, by containing the surfactant or the leveling agent, striation (film thickness irregularities) can be further prevented, or developability can be further improved.

Examples of the surfactant or the leveling agent include polyoxyethylene lauryl ether, polyoxyethylene stearyl ether, polyoxyethylene oleyl ether, and polyoxyethylene octylphenol ether. Examples of commercially available products of the surfactant or the leveling agent include MEGAFAC F171, F173, and R-08 (manufactured by DIC Corporation, trade name), FLUORAD FC430 and FC431 (manufactured by Sumitomo 3M Limited, trade name), and organosiloxane polymers KP341, KBM303, KBM403, and KBM803 (manufactured by Shin-Etsu Chemical Co., Ltd., trade name).

The blending amount in the case of using the surfactant or the leveling agent may be 0.001 to 5 parts by mass or 0.01 to 3 parts by mass with respect to 100 parts by mass of the component (A).

(Solvent)

When the photosensitive resin composition according to the embodiment contains a solvent dissolving or dispersing each component, coating onto a substrate is facilitated and a coating film having a uniform thickness can be formed.

Examples of the solvent include γ-butyrolactone, ethyl lactate, propylene glycol monomethyl ether acetate, benzyl acetate, n-butyl acetate, ethoxyethyl propionate, 3-methylmethoxy propionate, N-methyl-2-pyrrolidone, N,N-dimethylformamide, N,N-dimethylacetamide, dimethyl sulfoxide, hexamethylphosphorylamide, tetramethylenesulfone, diethyl ketone, diisobutyl ketone, methyl amyl ketone, cyclohexanone, propylene glycol monomethyl ether, propylene glycol monopropyl ether, propylene glycol monobutyl ether, and dipropylene glycol monomethyl ether. The solvent can be used singly or in combination of two or more kinds thereof.

The blending amount of the solvent is not particularly limited, and is preferably adjusted so that the ratio of the solvent in the photosensitive resin composition is 20 to 90% by mass.

In the photosensitive resin composition according to the present embodiment, development using an aqueous alkali solution such as sodium hydroxide, potassium hydroxide, sodium silicate, ammonia, ethylamine, diethylamine, triethylamine, triethanolamine, or tetramethylammonium hydroxide (TMAH) or development using an organic solvent such as cyclopentanone or 2-methoxy-1-methylethyl acetate can be performed. By using the photosensitive resin composition according to the present embodiment, a patterned cured film (permanent resist) whose appearance can be inspected with a simple method can be formed.

[Method for Inspecting Cured Film for Permanent Resist]

A method for inspecting a cured film for a permanent resist according to the present embodiment includes a step of coating a resin composition, which contains 100 parts by mass of a p-hydroxystyrene/styrene copolymer and 25 parts by mass of 4,4′,4″-ethylidenetris[2,6-(methoxymethyl)phenol], onto a glass substrate, drying the resin composition, and then performing a heating treatment at 200° C. to form a standard film with a thickness of 10 μm which contains a cured product of the resin composition, a step of coating a photosensitive resin composition onto a glass substrate, drying the photosensitive resin composition, and then performing a heating treatment to form a cured film containing a cured product of the photosensitive resin composition, and a step of measuring a fluorescence intensity of each of the standard film and the cured film at excitation wavelengths of 405 nm and 480 nm. The appearance of the permanent resist can be inspected with a simple method by selecting a cured film in which a fluorescence intensity of the cured film at an excitation wavelength of 405 nm or 480 nm is 10 times or more with respect to a fluorescence intensity of the standard film at an excitation wavelength of 405 nm or 480 nm.

The fluorescence intensity of the cured film at an excitation wavelength of 405 nm or 480 nm is preferably 12 times or more, more preferably 15 times or more, and further preferably 18 times or more with respect to the fluorescence intensity of the standard film at an excitation wavelength of 405 nm or 480 nm from the viewpoint that the appearance inspection of the permanent resist with a simple method is even more possible.

As the p-hydroxystyrene/styrene copolymer used for forming a standard film, for example, a p-hydroxystyrene/styrene copolymer having a molar ratio of p-hydroxystyrene/styrene of 80/20 and Mw of 10000 can be used. The time for the heating treatment at 200° C. may be 1.0 to 2.5 hours, 1.5 to 2.5 hours, or 1.8 to 2.2 hours.

[Method for Forming Permanent Resist]

A method for forming a permanent resist according to the present embodiment includes a step of coating the aforementioned photosensitive resin composition to a part or the entire surface of a substrate and drying the photosensitive resin composition to form a resin film (coating and drying step), a step of exposing at least a part of the resin film (exposure step), a step of developing the exposed resin film to form a patterned resin film (development step), and a step of heating the patterned resin film which has been patterned (heating treatment step). Hereinafter, examples of respective steps will be described.

(Coating and Drying Step)

First, the photosensitive resin composition is coated onto a substrate and dried to form a resin film. In this step, the photosensitive resin composition is spin coated onto a substrate such as a glass substrate, a semiconductor, a metal oxide insulator (for example, TiO₂, SiO₂, or the like), or silicon nitride using a spinner or the like to form a coating film. The substrate on which this coating film has been formed is dried using a hot plate, an oven, or the like. The drying temperature may be 80 to 140° C., 90 to 135° C., or 100 to 130° C., and the drying time may be 1 to 7 minutes, 1 to 6 minutes, or 2 to 5 minutes. As such, a resin film is formed on the substrate.

(Exposure Step)

Next, in the exposure step, the resin film formed on the substrate is irradiated with active light rays such as ultraviolet rays, visible light rays, and radiation through a mask. In the aforementioned photosensitive resin composition, the component (A) has high transparency for i-rays, and thus irradiation with i-rays can be suitably used. After exposure, as necessary, post-exposure baking (PEB) can also be performed. The temperature for post-exposure baking is preferably 70° C. to 140° C., and the time for post-exposure baking is preferably 1 to 5 minutes.

(Development Step)

In the development step, the exposed area or unexposed area of the resin film after the exposure step is removed with a developing solution for patterning of the resin film, thereby obtaining a patterned resin film. In a case where the photosensitive resin composition is a positive type, the exposed area is removed with a developing solution. In a case where the photosensitive resin composition is a negative type, the unexposed area is removed with a developing solution.

As the developing solution in the case of performing development using an aqueous alkali solution, for example, aqueous alkali solutions such as sodium hydroxide, potassium hydroxide, sodium silicate, ammonia, ethylamine, diethylamine, triethylamine, triethanolamine, and tetramethylammonium hydroxide (TMAH) are suitably used. The base concentration of these aqueous solutions is preferably set to 0.1 to 10% by mass. An alcohol or a surfactant can also be added to the developing solution for use. These each may be blended in a range of 0.01 to 10 parts by mass or 0.1 to 5 parts by mass with respect to 100 parts by mass of the developing solution.

As the developing solution in the case of the development using an organic solvent, for example, a good solvent such as cyclopentanone, N,N-dimethylformamide, dimethyl sulfoxide, N,N-dimethylacetamide, N-methyl-2-pyrrolidone, γ-butyrolactone, or acetic acid ester, and a mixed solvent that includes these good solvents and a poor solvent such as a lower alcohol, water, or an aromatic hydrocarbon are used.

(Heating Treatment Step)

In the heating treatment step, a patterned cured film (permanent resist) can be formed by heat-treating the patterned resin film. The heating temperature in the heating treatment step is preferably 160° C. or higher and may be 170 to 260° C., 180 to 250° C., or 190 to 240° C. from the viewpoint of sufficiently preventing damage to an electronic device by heat.

The heating treatment can be performed, for example, using an oven such as a quartz tube furnace, a hot plate, rapid thermal annealing, a vertical diffusion furnace, an infrared curing furnace, an electron beam curing furnace, or a microwave curing furnace. Furthermore, any of an atmosphere of air and an inert atmosphere of nitrogen or the like can also be selected, but treatment under a nitrogen atmosphere is desirable as it can prevent oxidation of the pattern. Since the aforementioned heating temperature range is lower than the conventional heating temperature, it is possible to minimize damage to a substrate and an electronic device. Therefore, using the method for producing a patterned cured film according to the present embodiment allows high-yield production of an electronic device.

The time for the heating treatment in the heating treatment step may be a time sufficient for the photosensitive resin composition to cure, but is generally preferred to be 5 hours or shorter for satisfactory balance with working efficiency.

The heating treatment can also be performed using a microwave curing apparatus or a frequency-variable microwave curing apparatus, in addition to the aforementioned oven. By using these apparatuses, only the resin film can be effectively heated while the temperature of a substrate and an electronic device is maintained at a desired temperature (for example, 200° C. or lower) (see J. Photopolym. Sci. Technol., 18, 327-332 (2005)).

[Permanent Resist]

A permanent resist according to the present embodiment contains a cured product of a photosensitive resin composition which contains a base polymer and a compound having an absorption at 400 to 500 nm and emitting light by light irradiation, in which a fluorescence intensity of the permanent resist at an excitation wavelength of 405 nm or 480 nm is 10 times or more with respect to a fluorescence intensity of a standard film with a thickness of 10 μm, which contains a cured product of a resin composition containing 100 parts by mass of a p-hydroxystyrene/styrene copolymer and 25 parts by mass of 4,4′,4″-ethylidenetris[2,6-(methoxymethyl)phenol], at an excitation wavelength of 405 nm or 480 nm.

Since the permanent resist according to the present embodiment exerts the light-emitting function by light irradiation, a defect of a resist pattern can be detected in a short time by inspecting the appearance of the resist pattern on the basis of the reflected light from the substrate on which the resist pattern is formed.

The fluorescence intensity of the permanent resist at an excitation wavelength of 405 nm or 480 nm is preferably 12 times or more, more preferably 15 times or more, and further preferably 18 times or more with respect to the fluorescence intensity of the standard film at an excitation wavelength of 405 nm or 480 nm from the viewpoint that the appearance inspection of the permanent resist with a simple method is even more possible.

The thickness of the permanent resist may be 2 to 30 μm, 3 to 20 μm, or 5 to 15 μm.

The permanent resist according to the present embodiment can be used as an interlayer insulation layer or a surface protective layer of a semiconductor element. A semiconductor element including an interlayer insulation layer or a surface protective layer formed from a cured film of the aforementioned photosensitive resin composition and an electronic device including this semiconductor element can be produced. The semiconductor element may be, for example, a memory, a package, or the like having a multilayer wiring structure, a redistribution structure, or the like. Examples of the electronic device include a cellular phone, a smart phone, a tablet type terminal, a personal computer, and a hard disk suspension. By including the patterned cured film formed of the photosensitive resin composition of the present embodiment, a semiconductor element and an electronic device with excellent reliability can be provided.

### EXAMPLES

Hereinafter, the present invention will be specifically described on the basis of Examples; however, the present invention is not limited thereto. Materials used in Examples and Comparative Examples are shown below.

(Base Polymer)

The following base polymers were prepared as the component (A).

A1: Copolymer of p-hydroxystyrene/styrene (molar ratio of p-hydroxystyrene/styrene: 80/20, Mw: 10000)
A2: Novolac type phenolic resin (molar ratio of m-cresol/p-cresol: 40/60, Mw: 10000)
A3: Polybenzoxazole precursor having a structure represented by the following formula (Mw: 30000)

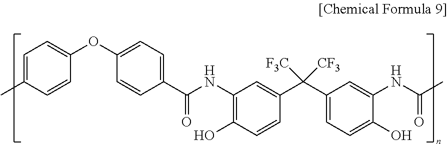

A4: Polyimide precursor having a structure represented by the following formula (Mw: 23000)

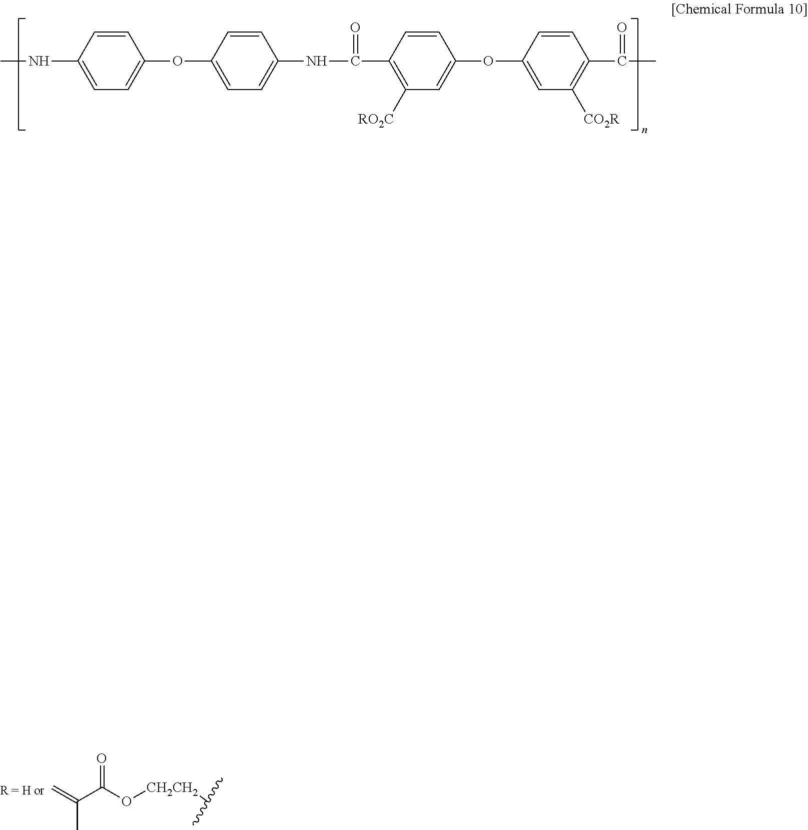

Mw was derived using a GPC method by conversion using a calibration curve of standard polystyrene. The calibration curve was approximated by the cubic formula of the universal calibration curve using five sets of standard polystyrene samples (PStQuick MP-H, PStQuick B [manufactured by Tosoh Corporation, trade name]) according to JIS K 7252-2 (2016). Specifically, Mw was measured by the following device and under the following conditions.

Detector: L-2490 RI (manufactured by Hitachi High-Tech Corporation) Column: Gelpack GL-R440+R450+R400M (manufactured by Hitachi High-Tech Corporation)

### Eluent: Tetrahydrofuran (THF)

Measurement temperature: 40° C.
Flow rate: 2.05 mL/min
Concentration: 5 mg/mL

B1 (thermal crosslinking agent): 4,4′,4″-Ethylidenetris[2,6-(methoxymethyl)phenol] (manufactured by Honshu Chemical Industry Co., Ltd., trade name “HMOM-TPPA”) B2 (photopolymerizable compound): Polyethylene glycol #200 dimethacrylate (manufactured by SHIN-NAKAMURA CHEMICAL Co., Ltd.)

C1 (photo-acid generator): 1-Naphthoquinone-2-diazide-5-sulfonic acid ester of 1,1-bis(4-hydroxyphenyl)-1-[4-{1-(4-hydroxyphenyl)-1-methylethyl}phenyl]ethane (esterification rate: about 90%, manufactured by Daito Chemix Corporation, trade name “PA28”) C2 (photopolymerization initiator): Ethanone, 1-[9-ethyl-6-(2-methylbenzoyl)-9 H-carbazole-3-yl]-,1-(o-acetyl oxime) (manufactured by BASF, trade name “IRGACURE OXE02”)

(Compound Having Absorption Peak at 360 to 500 nm and Emitting Light by Light Irradiation)

X1 to X6 shown in Table 1 were prepared as the component (X).

TABLE 1

| | | | Melting |
|---|---|---|---|
| | | λmax | point |
| | | (nm) | (° C.) |
| X1 | 3,3′-Carbonylbis(7-diethylaminocoumarin) | 456 | 217 |
| X2 | 3-Benzoyl-7-diethylaminocoumarin | 425 | 151 |
| X3 | 7-Diethylamino-3-phenylcoumarin | 397 | 153 |
| X4 | Coumarin 102 | 390 | 151 |
| X5 | 7-Diethylaminocoumarin | 360 | 89 |
| X6 | 2,5-Bis(5-tert-butyl-2-benzoxazolyl)thiophene | 373 | 199 to |
| | | | 203 |

(Material Having Absorption Peak at 360 to 500 nm but not Emitting Fluorescence)

Y1: Dihydroxybenzophenone-based ultraviolet absorbing agent (manufactured by BASF, trade name “Uvinul 3050”)
Y2: Fa-type oxazine (manufactured by SHIKOKU CHEMICALS CORPORATION)

### Examples 1 to 8

Respective components in blending amounts (parts by mass) shown in Table 2 were mixed with ethyl lactate so that the solid content was 30% by mass, and this mixture was subjected to pressure filtration using a PTFE filter with 0.2 μm pores, thereby preparing photosensitive resin compositions.

### Examples 9 and 10

Respective components in blending amounts (parts by mass) shown in Table 2 were mixed with N-methyl-2-pyrrolidone (NMP) so that the solid content was 30% by mass, and this mixture was subjected to pressure filtration using a PTFE filter with 0.2 μm pores, thereby preparing photosensitive resin compositions.

### Comparative Example 1

Respective components in blending amounts (parts by mass) shown in Table 3 were mixed with ethyl lactate so that the solid content was 35% by mass, and this mixture was subjected to pressure filtration using a PTFE filter with 0.2 μm pores, thereby preparing a resin composition for a standard film.

### Comparative Examples 2 to 5

Respective components in blending amounts (parts by mass) shown in Table 3 were mixed with ethyl lactate so that the solid content was 30% by mass, and this mixture was subjected to pressure filtration using a PTFE filter with 0.2 μm pores, thereby preparing photosensitive resin compositions.

### Comparative Examples 6 and 7

Respective components in blending amounts (parts by mass) shown in Table 3 were mixed with NP so that the solid content was 30% by mass, and this mixture was subjected to pressure filtration using a PTFE filter with 0.2 μm pores, thereby preparing photosensitive resin compositions.

[Evaluation]

(Cured film)

The resin composition of Comparative Example 1 was spin coated onto a glass substrate, heated at 120° C. for 3 minutes, dried, and then heat-treated using an inert gas oven (manufactured by Koyo Thermo Systems Co., Ltd., trade name “INH-9CD-S”) in nitrogen at a temperature of 200° C. (rising a temperature for 1 hour) for 2 hours, thereby forming a cured film of the resin composition having a thickness of 10 μm on the glass substrate. This cured film of the resin composition was used as a standard film. The same operation was also performed for the photosensitive resin compositions of Examples and Comparative Examples, thereby a cured film of the photosensitive resin composition on the glass substrate.

(Absorbance)

The absorption spectrum of the cured film formed on the glass substrate at 300 to 600 nm was measured using a spectrophotometer (manufactured by Hitachi, Ltd., trade name “U-4100”). Numerical values obtained by converting the absorbance at 405 nm and 480 nm into a thickness of 10 μm are shown in Tables 2 and 3.

(Fluorescence Intensity)

The fluorescence spectrum of the cured film formed on the glass substrate at a wavelength of 230 to 800 nm was measured under the following conditions using a spectrofluorometric measurement device (manufactured by HORIBA, Ltd., trade name “Modular Fluorescence Spectrophotometer Fluorolog-3”), the emission intensity was standardized with the excitation light intensity at each wavelength, and light emission in a 22.5° direction with respect to the excitation light was observed. The fluorescence intensities at excitation wavelengths of 405 nm and 480 nm are shown in Tables 2 and 3.

Light source: Xenon lamp
Detector: PMT (photomultiplier tube)
Slit width: excitation side 3 mm, observation side 3 mm
Time constant: 0.2 seconds
Measurement mode: Sc/Rc

TABLE 2

| Example | | 1 | 2 | 3 | 4 | 5 | 6 | 7 | 8 | 9 | 10 |
|---|---|---|---|---|---|---|---|---|---|---|---|
| A1 | | 100 | 100 | 100 | 100 | 100 | 100 | 100 | — | — | — |
| A2 | | — | — | — | — | — | — | — | 100 | — | — |
| A3 | | — | — | — | — | — | — | — | — | 100 | — |
| A4 | | — | — | — | — | — | — | — | — | — | 100 |
| B1 | | 25 | 25 | 25 | 25 | 25 | 25 | 25 | 25 | 25 | — |
| B2 | | — | — | — | — | — | — | — | — | — | 15 |
| C1 | | 15 | 15 | 15 | 15 | 15 | 15 | 15 | 10 | 10 | — |
| C2 | | — | — | — | — | — | — | — | — | — | 2 |
| X1 | | 0.25 | 0.50 | | — | — | — | — | 0.50 | 0.50 | 0.50 |
| X2 | | — | — | 0.50 | — | — | — | — | — | — | — |
| X3 | | — | — | — | 0.50 | — | — | — | — | — | — |
| X4 | | — | — | — | — | 0.50 | — | — | — | — | — |
| X5 | | — | — | — | — | — | 0.50 | — | — | — | — |
| X6 | | — | — | — | — | — | — | 0.50 | — | — | — |
| Absorbance | 405 nm | 0.31 | 0.39 | 0.44 | 0.50 | 0.34 | 0.46 | 0.42 | 0.33 | 0.54 | 0.98 |
| [a.u./10 μm] | 480 nm | 0.34 | 0.66 | 0.14 | 0.07 | 0.11 | 0.07 | 0.07 | 0.63 | 0.75 | 0.64 |
| Fluorescence | 405 nm | 4.5 × 10⁵ | 4.7 × 10⁵ | 1.6 × 10⁶ | 6.2 × 10⁶ | 1.5 × 10⁶ | 1.9 × 10⁶ | 1.2 × 10⁶ | 4.3 × 10⁵ | 3.7 × 10⁵ | 3.6 × 10⁵ |
| intensity | 480 nm | 9.2 × 10⁵ | 1.3 × 10⁶ | 2.6 × 10⁵ | 7.6 × 10⁵ | 1.8 × 10⁵ | 1.0 × 10⁵ | 2.3 × 10⁵ | 8.8 × 10⁵ | 8.9 × 10⁵ | 1.1 × 10⁶ |
| [a.u.] | | | | | | | | | | | |

TABLE 3

| Comparative Example | | 1 | 2 | 3 | 4 | 5 | 6 | 7 |
|---|---|---|---|---|---|---|---|---|
| A1 | | 100 | 100 | 100 | 100 | — | — | — |
| A2 | | — | — | — | — | 100 | — | — |
| A3 | | — | — | — | — | — | 100 | — |
| A4 | | — | — | — | — | — | — | 100 |
| B1 | | 25 | 25 | 25 | 25 | 25 | 25 | — |
| B2 | | — | — | — | — | — | — | 15 |
| C1 | | — | 15 | 15 | 15 | 10 | 10 | — |
| C2 | | — | — | — | — | — | — | 2 |
| Y1 | | — | — | 1.0 | — | — | — | — |
| Y2 | | — | — | — | 5.0 | — | — | — |
| Absorbance | 405 nm | 0.02 | 0.20 | 0.37 | 0.49 | 0.14 | 0.35 | 0.60 |
| [a.u./10 μm] | 480 nm | 0.01 | 0.07 | 0.06 | 0.19 | 0.05 | 0.15 | 0.05 |
| Fluorescence | 405 nm | 0.5 × 10⁵ | 3.4 × 10⁵ | 3.3 × 10⁵ | 4.1 × 10⁵ | 2.0 × 10⁵ | 1.4 × 10⁵ | 2.1 × 10⁵ |
| intensity | 480 nm | 0.5 × 10⁵ | 2.4 × 10⁵ | 2.5 × 10⁵ | 3.2 × 10⁵ | 0.6 × 10⁵ | 1.0 × 10⁵ | 1.4 × 10⁵ |
| [a.u.] | | | | | | | | |

As shown in Table 2, it was confirmed that each of the cured films formed using the photosensitive resin compositions of Examples 1 to 10 has a high fluorescence intensity at an excitation wavelength of 405 nm or 480 nm.

1. A method for forming a permanent resist, the method comprising:
a step of coating a photosensitive resin composition, which contains a base polymer and a compound having an absorption peak at 360 to 500 nm and emitting light by light irradiation, to a part or the entire surface of a substrate and drying the photosensitive resin composition to form a resin film;
a step of exposing at least a part of the resin film;
a step of developing the exposed resin film to form a patterned resin film; and
a step of heating the patterned resin film.

2. The method for forming a permanent resist according to claim 1, wherein a melting point of the compound is 80 to 250° C.

3. The method for forming a permanent resist according to claim 1, wherein the base polymer contains a resin having a phenolic hydroxyl group or a resin having an ethylenically unsaturated group with photopolymerizability.

4. The method for forming a permanent resist according to claim 3, wherein the resin having a phenolic hydroxyl group is at least one selected from the group consisting of a hydroxystyrene-based resin, a phenolic resin, and a polybenzoxazole precursor.

5. The method for forming a permanent resist according to claim 3, wherein the resin having an ethylenically unsaturated group with photopolymerizability is a polyimide precursor.

6. The method for forming a permanent resist according to claim 1, wherein a temperature at which the patterned resin film is heated is 160° C. or higher.

7. A photosensitive resin composition for a permanent resist, the photosensitive resin composition comprising:
a base polymer; and
a compound having an absorption peak at 360 to 500 nm and emitting light by light irradiation.

8. The photosensitive resin composition according to claim 7, wherein a melting point of the compound is 80 to 250° C.

9. The photosensitive resin composition according to claim 7, wherein the base polymer contains a resin having a phenolic hydroxyl group or a resin having an ethylenically unsaturated group with photopolymerizability.

10. The photosensitive resin composition according to claim 9, wherein the resin having a phenolic hydroxyl group is at least one selected from the group consisting of a hydroxystyrene-based resin, a phenolic resin, and a polybenzoxazole precursor.

11. The photosensitive resin composition according to claim 9, wherein the resin having an ethylenically unsaturated group with photopolymerizability is a polyimide precursor.

12. A permanent resist comprising a cured product of a photosensitive resin composition which contains a base polymer and a compound having an absorption peak at 360 to 500 nm and emitting light by light irradiation, wherein
a fluorescence intensity of the permanent resist at an excitation wavelength of 405 nm or 480 nm is 10 times or more with respect to a fluorescence intensity of a standard film with a thickness of 10 μm, which contains a cured product of a resin composition containing 100 parts by mass of a p-hydroxystyrene/styrene copolymer and 25 parts by mass of 4,4′,4″-ethylidenetris[2,6-(methoxymethyl)phenol], at an excitation wavelength of 405 nm or 480 nm.

13. The permanent resist according to claim 12, wherein a melting point of the compound is 80 to 250° C.

14. The permanent resist according to claim 12, wherein the base polymer contains a resin having a phenolic hydroxyl group or a resin having an ethylenically unsaturated group with photopolymerizability.

15. The permanent resist according to claim 14, wherein the resin having a phenolic hydroxyl group is at least one selected from the group consisting of a hydroxystyrene-based resin, a phenolic resin, and a polybenzoxazole precursor.

16. The permanent resist according to claim 14, wherein the resin having an ethylenically unsaturated group with photopolymerizability is a polyimide precursor.

17. A method for inspecting a cured film for a permanent resist, the method comprising:
a step of coating a resin composition, which contains 100 parts by mass of a p-hydroxystyrene/styrene copolymer and 25 parts by mass of 4,4′,4″-ethylidenetris[2,6-(methoxymethyl)phenol], onto a glass substrate, drying the resin composition, and then performing a heating treatment at 200° C. to form a standard film with a thickness of 10 μm which contains a cured product of the resin composition;
a step of coating a photosensitive resin composition onto a glass substrate, drying the photosensitive resin composition, and then performing a heating treatment to form a cured film containing a cured product of the photosensitive resin composition; and
a step of measuring a fluorescence intensity of each of the standard film and the cured film at excitation wavelengths of 405 nm and 480 nm, wherein
a cured film in which a fluorescence intensity of the cured film at an excitation wavelength of 405 nm or 480 nm is 10 times or more with respect to a fluorescence intensity of the standard film at an excitation wavelength of 405 nm or 480 nm is selected.
